(19) United States
(12) Patent Application Publication
(10) Pub. No.: US 2015/0348805 A1
(43) Pub. Date: Dec. 3, 2015

(54) SUBSTRATE TREATING APPARATUS AND METHOD

(71) Applicant: Semes Co., Ltd., Cheonan-si (KR)

(72) Inventors: Bong Joo KIM, Cheonan-si (KR); Seung Ho LEE, Cheonan-si (KR); Yong-Hyoun CHOI, Cheonan-si (KR); Byung-Man KANG, Cheonan-si (KR)

(21) Appl. No.: 14/716,996

(22) Filed: May 20, 2015

(30) Foreign Application Priority Data
May 29, 2014 (KR) 10-2014-0065348

(51) Int. Cl. H01L 21/67; H01L 21/3213; H01L 21/311

(52) U.S. Cl. CPC H01L 21/6708; H01L 21/31111; H01L 21/32134

(57) ABSTRACT

The inventive concepts provide an apparatus for treating a substrate. The apparatus includes a housing having a treatment space therein, a support unit supporting the substrate in the treatment space, a nozzle unit discharging a solution onto the substrate supported by the support unit, and a solution supply unit supplying the solution to the nozzle unit. The solution supply unit includes a solution supply line connected to the nozzle unit, a heating member installed on the solution supply line to heat the solution, and a recovery line diverging from the solution supply line at a first point disposed downstream from the heating member.

### CROSS-REFERENCE TO RELATED APPLICATION

This U.S. non-provisional patent application claims priority under 35 U.S.C. §119 to Korean Patent Application No. 10-2014-0065348, filed on May 29, 2014, in the Korean Intellectual Property Office, the disclosure of which is hereby incorporated by reference in its entirety.

### BACKGROUND

The inventive concepts relate to a substrate-treating apparatus and a method of treating a substrate using the same.

Generally, a plurality of layers (e.g., a poly-crystalline layer, an oxide layer, a nitride layer, and a metal layer) may be formed on a wafer used as a semiconductor substrate during processes of manufacturing a semiconductor device. A photoresist layer may be coated on the layer, and a pattern of a photomask may be transferred to the photoresist layer by an exposure process. Thereafter, a desired pattern may be formed on the wafer by an etching process.

Etching apparatuses may be generally categorized as any one of dry etching apparatuses and wet etching apparatuses. The wet etching apparatuses may treat a substrate by means of a plurality of treatment solutions, e.g., an etching solution, a cleaning solution, and a rinse solution. These substrate-treating apparatuses may be used to perform a process of etching a unnecessary portion of a layer formed on the substrate and/or a process of cleaning a foreign material remaining on a treated surface of the substrate.

FIG. 1 is a graph showing relation between an etch rate and a temperature of phosphoric acid. High-temperature phosphoric acid may be needed to obtain a high etch rate. Generally, the etch rate may increase by 10% as the temperature of the phosphoric acid increases by 10 degrees Celsius. Thus, it may be important to supply a high-temperature solution onto the substrate. To achieve this, the solution may be heated in a supply tank and then be supplied. However, the temperature of the solution may be reduced while the solution passes through a supply line and then is supplied to a nozzle unit. As the temperature of the solution becomes higher, the reduction amount of the temperature of the solution may become greater. In addition, if an additive is mixed with the solution to increase the etch rate, the temperature of the additive may greatly affect the temperature reduction of the solution.

### SUMMARY

Embodiments of the inventive concepts may provide a substrate-treating apparatus capable of improving an etch rate.

Embodiments of the inventive concepts may also provide a substrate-treating apparatus capable of effectively controlling a temperature of an etching solution.

In one aspect, a substrate-treating apparatus may include a treatment container having a treatment space therein, a support unit supporting the substrate in the treatment space, a nozzle unit discharging a solution onto the substrate supported by the support unit, and a solution supply unit supplying the solution to the nozzle unit. The solution supply unit may include a solution supply line connected to the nozzle unit, a heating member installed on the solution supply line to heat the solution, and a recovery line diverging from the solution supply line at a first point disposed downstream from the heating member.

In an embodiment, a cooling unit may be installed on the recovery line to cool the solution.

In an embodiment, the apparatus may further include a controller controlling the solution supply unit, and a switching valve installed at the first point to switch a supply direction of the solution between the nozzle unit and the recovery line. The controller may control the switching valve to supply the solution to the nozzle unit when a process is performed, and the controller may control the switching valve to supply the solution to the recovery line when the process is not performed.

In an embodiment, the first point may be adjacent to the heating member.

In an embodiment, the cooling unit may be adjacent to the switching valve.

In an embodiment, the nozzle unit may include a body defining an inner space in which the solution is stored, an outlet discharging the solution onto the substrate, and an exhaust pipe exhausting an air bubble formed in the inner space by the solution to the outside of the body.

In an embodiment, he apparatus may further include an additive supply line connected to the body and supplying an additive.

In an embodiment, the apparatus may further include an additive supply line connected to the solution supply line and supplying an additive.

In an embodiment, the additive supply line may be connected to the solution supply line at a second point disposed downstream from the first point.

In an embodiment, the additive may include a chemical material of which a boiling point is different from that of the solution.

In an embodiment, the heating member may be an in-line heater installed in-line on the solution supply line.

In an embodiment, the solution may include phosphoric acid, and the process may be a process of etching a nitride layer formed on the substrate.

In another aspect, a method of treating a substrate using the apparatus of claim 1 may be provided. The method may include supplying the solution for treating a process from the solution supply unit to the nozzle unit. The solution may be heated by the heating member on the solution supply line and may be then supplied.

In still another aspect, a method of treating a substrate by supplying a solution for treating a process onto a substrate through a nozzle unit may be provided. The method may include supplying the solution to the nozzle unit by a solution supply unit. The solution may be heated by a heating member installed on a solution supply line and may be then supplied to the nozzle unit.

### BRIEF DESCRIPTION OF THE DRAWINGS

The inventive concepts will become more apparent in view of the attached drawings and accompanying detailed description.

FIG. 1 is a graph showing relation between an etch rate and a temperature of phosphoric acid.

FIG. 2 is illustrates a substrate-treating system according to an embodiment of the inventive concepts.

FIG. 3 is a plan view illustrating a substrate-treating apparatus according to an embodiment of the inventive concepts.

FIG. 4 is a side cross-sectional view illustrating a substrate-treating apparatus according to an embodiment of the inventive concepts.

FIG. 5 is a schematic diagram illustrating a solution supply unit according to an embodiment of the inventive concepts.

FIG. 6 is a diagram illustrating a solution supply line of FIG. 5.

FIG. 7 is a diagram illustrating an embodiment of the inside of the solution supply line of FIG. 6.

FIG. 8 illustrates the inside of a nozzle unit of FIG. 5.

FIG. 9 illustrates a fluid flowing through the nozzle unit of FIG. 8.

FIG. 10 is a diagram illustrating a solution supply unit according to another embodiment of the inventive concepts.

FIG. 11 is a diagram illustrating a solution supply line of FIG. 10.

FIG. 12 illustrates the inside of a nozzle unit of FIG. 11.

FIG. 13 illustrates a fluid flowing through the nozzle unit of FIG. 12.

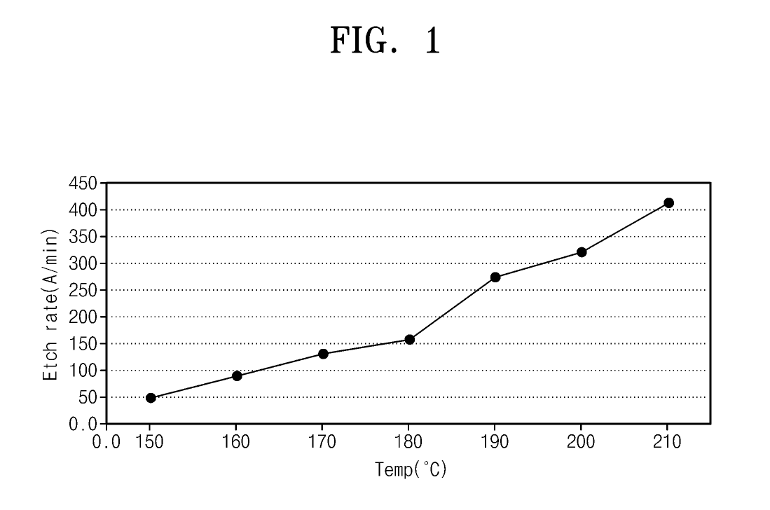

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

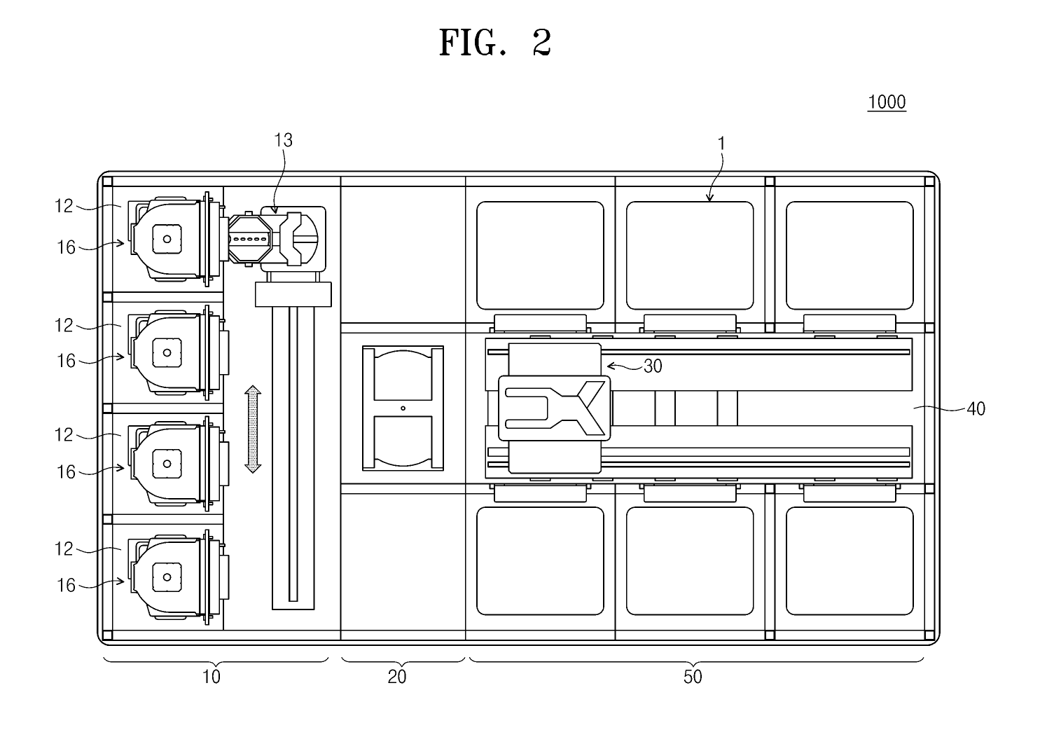

FIG. 2 is illustrates a substrate-treating system according to an embodiment of the inventive concepts.

Referring to FIG. 2, a substrate-treating system 1000 according to the inventive concepts may include an index part 10, a buffer part 20, and a treatment part 50. The index part 10, the buffer part 20, and the treatment part 50 may be arranged in a line. Hereinafter, a direction in which the index part 10, the buffer part 20, and the treatment part 50 are arranged is defined as a first direction. In addition, a direction perpendicular to the first direction in a plan view is defined as a second direction, and a direction perpendicular to a plane including the first and second directions is defined as a third direction.

The index part 10 may be disposed at the front of the substrate-treating system 1000 in the first direction. The index part 10 may include a load port 12 and an index robot 13. The load port 12 may be provided in plurality. For example, four load ports 12 may be provided as illustrated in FIG. 2. The load port 12 may be disposed at the front of the index port 10 in the first direction. The load ports 12 may be arranged in the second direction. The number of the load ports 12 may be increased or reduced according to process efficiency and a foot print condition of the substrate-treating system 1000. A carrier 16 (e.g., a cassette or a FOUP) may be safely mounted on each of the load ports 12. The carrier 16 may receive a substrate W which is to be provided in a process, or a substrate W on which the process is completed. A plurality of slits may be formed in the carrier 16 to receive the substrates W in a horizontal state to the ground.

The index robot 13 may be disposed to be adjacent to the load port 12 in the first direction. The index robot 13 may be installed between the load portion 12 and the buffer part 20. The index robot 13 may transfer a substrate W staying in an upper portion of the buffer part 20 to the carrier 16 or may transfer a substrate W staying in the carrier 16 into a lower portion of the buffer part 20.

The buffer part 20 may be installed between the index part 10 and the treatment part 50. The buffer part 20 is a place temporarily receiving the substrate W which is to be provided in the process and is transferred by the index robot 13, or the process-completed substrate W which is transferred by a main transfer robot 30.

The main transfer robot 30 may be installed in a movement path 40 and may transfer a substrate W between the buffer part 20 and each of the substrate-treating apparatuses 1. The main transfer robot 30 may transfer the substrate W, which stays in the buffer part 20 and is to be provided in the process, to each of the substrate-treating apparatuses 1 or may transfer the process-completed substrate W from each of the substrate-treating apparatus 1 into the buffer part 20.

The movement path 40 may be disposed along the first direction in the treatment part 50. The movement path 40 provides a path along which the main transfer robot 30 moves. The substrate-treating apparatuses 1 may be disposed at both sides of the movement path 40 to face each other and may be arranged in the first direction. The main transfer robot 30 may move in the movement path 40 along the first direction, and a movement rail may be installed in the movement path 40. The movement rail may be capable of vertically moving between lower and upper portions of the substrate-treating apparatus 1 and between the lower and upper portions of the buffer part 20.

The substrate-treating apparatuses 1 may be disposed to face each other at both sides of the movement path 40 in which the main transfer robot 30 is installed. The substrate-treating system 100 may include a plurality of the substrate-treating apparatuses 1 which are disposed at lower and upper floors. However, the number of the substrate-treating apparatuses 1 may be increased or reduced according to the process efficiency and the foot print condition of the substrate-treating system 1000. Each of the substrate-treating apparatuses 1 may be formed of an independent housing, so an independent process of treating a substrate may be performed in each of the substrate-treating apparatuses 1.

An apparatus of cleaning a substrate using treatment fluids (e.g., high-temperature sulfuric acid, an alkaline solution (including ozone water), an acidic solution, a rinse solution, and a gas including a drying gas (IPA) will be described as an example in the following embodiment. However, the inventive concepts are not limited thereto. In other embodiments, the substrate-treating apparatus 1 according to the inventive concepts may be applied to various kinds of apparatuses such as an apparatus performing an etching process that etches a layer during rotation of a substrate.

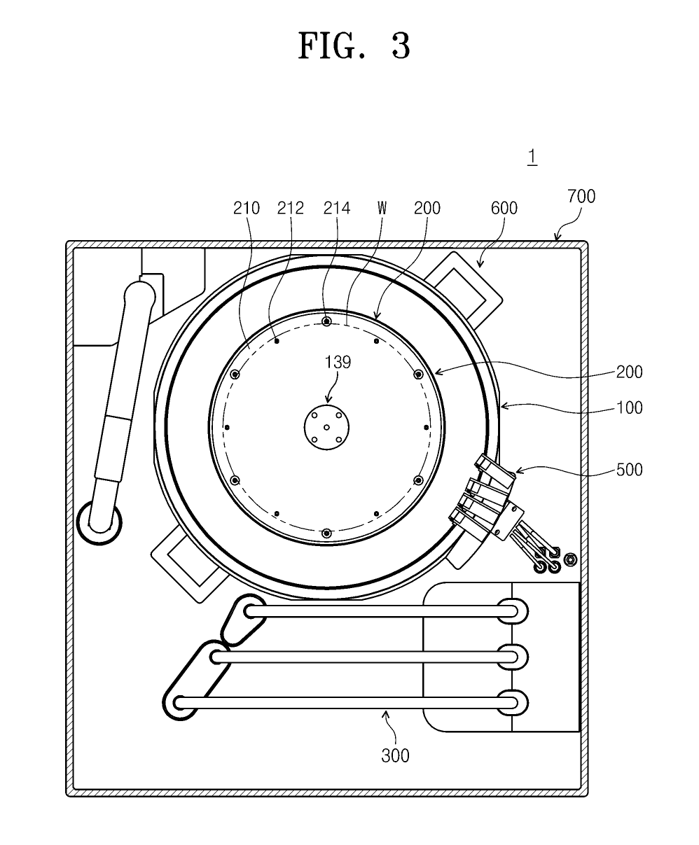

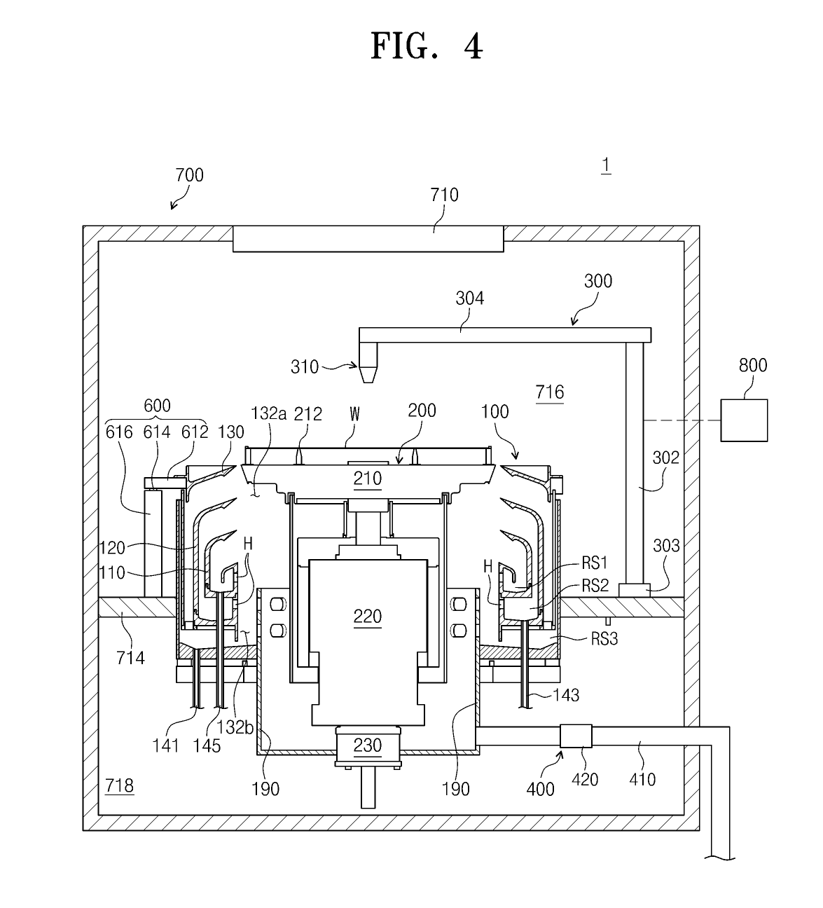

FIG. 3 is a plan view illustrating a substrate-treating apparatus according to an embodiment of the inventive concepts. FIG. 4 is a side cross-sectional view illustrating a substrate-treating apparatus according to an embodiment of the inventive concepts. In FIG. 4, a fixed nozzle member is omitted to the purpose of ease and convenience in the drawing.

In the present embodiment, a semiconductor substrate is used as the substrate treated by a single wafer-type substrate-treating apparatus 1. However, the inventive concepts are not limited thereto. In other embodiments, the substrate-treating apparatus 1 may be applied to various kinds of substrates such as a glass substrate.

Referring to FIGS. 3 and 4, the substrate-treating apparatus 1 according to the inventive concepts may include a process chamber 700 and a solution supply unit 800. The process chamber 700 may perform a process on a substrate by means of a solution. The process chamber 700 may perform the process on the substrate while maintaining the horizontal state of the substrate. The process may be a process of etching a nitride layer formed on the substrate. At this time, the solution may include phosphoric acid. The solution supply unit 800 may supply a treatment solution into the process chamber 700. In an embodiment, the solution supply unit 800 may supply the treatment solution through a nozzle unit 310. Alternatively, the process chamber 700 may be an apparatus that removes a foreign material and a layer remaining on a surface of the substrate by means of at least one of various treatment solutions. The process chamber 700 may include a treatment container 100, a support unit 200, a nozzle part 300, an exhaust member 400, and a fixed nozzle 500.

The process chamber 700 may provide a sealed inner space, and a fan filter unit 710 may be installed at an upper portion of the process chamber 700. The fan filter unit 710 may generate a vertical air current within the process chamber 700.

The fan filter unit 710 may include a filter and an air supply fan which are modularized into one unit. The fan filter unit 710 may filter clean air and may then supply the filtered air into the process chamber 700. The clean air may pass through the fan filter unit 710 and may be then supplied into the process chamber 700 to form the vertical air current. The vertical air current may provide a uniform air current onto the substrate. Contamination materials (e.g., fumes) occurring in the process of treating the surface of the substrate by means of the treatment fluid may be exhausted together with the air into the exhaust member 400 through intake ducts of the treatment container 100, so high cleanliness may be maintained within the treatment container 100.

As illustrated in FIG. 4, the process chamber 700 may be divided into a process region 716 and a maintenance region 718 by a horizontal partition 714. Even though a portion of the maintenance region 718 is shown in the drawing, the maintenance region 718 may correspond to a space that receives recovery lines 141, 143 and 145 connected to the treatment container 100, a sub-exhaust line 410, a driving part of an elevating unit, a driving part connected to the movable nozzle units 310 of the nozzle part 300, and a supply line. It is preferable that the maintenance region 718 is isolated from the process region 716 in which the substrate is treated.

The treatment container 100 may have cylindrical shape having an opened top end and may provide a treatment space in which the substrate W is treated. The opened top end of the treatment container 100 may be provided as a path through which the substrate W is carried into and/or carried from the treatment container 100. The support unit 200 may be disposed in the treatment space. The support unit 200 may support and rotate the substrate W during the process.

The treatment container 100 may provide an upper space 132a and a lower space 132b. A spin head 210 is disposed in the upper space 132a, and a lower space 132b is separated from the upper space 132a by the spin head 210. An exhaust duct 190 for forced exhaust may be connected to a bottom end portion of the lower space 132b. First, second, and third intake ducts 110, 120, and 130 may be vertically stacked in the upper space 132a. The first to third intake ducts 110, 120, and 130 may have ring shapes and may absorb the solution and gas scattered from the rotated substrate W.

The first, second, and third intake ducts 110, 120, and 130 having the ring shapes may have exhaust ports H connected to one common ring-shaped space corresponding to the lower space of the container 100. The exhaust duct 190 connected to the exhaust member 400 may be provided to the lower space 132b.

In detail, each of the first to third intake ducts 110, 120, and 130 may include a bottom surface having a ring shape and a sidewall extending from the bottom surface to have a cylindrical shape. The second intake duct 120 may surround the first intake duct 110 and may be spaced apart from the first intake duct 110. The third intake duct 130 may surround the second intake duct 120 and may be spaced apart from the second intake duct 120.

The first to third intake ducts 110, 120, and 130 may provide first to third recovery spaces RS1, RS2, and R3 into which an air current including the treatment solution and fumes scattered from the substrate W flows. The first recovery space RS1 may be defined by the first intake duct 110, the second recovery space RS2 may be defined by a space between the first and second intake ducts 110 and 120, and the third recovery space RS3 may be defined by a space between the second and third intake ducts 120 and 130.

A top surface of each of the first to third intake ducts 110, 120, and 130 may have an opening and an inclined surface. The opening may be formed in a central portion of the top surface of each of the first to third intake ducts 110, 120, and 130. In each of the first to third intake ducts 110, 120, and 130, a distance between the inclined surface and the bottom surface may gradually increase as a distance from the sidewall toward the opening increases. Thus, the treatment solution scattered from the substrate W may flow into the recovery spaces RS1, RS2, and RS3 along the top surfaces of the first to third intake ducts 110, 120, and 130.

A first treatment solution flowing into the first recovery space RS1 may be exhausted to the outside through a first recovery line 141. A second treatment solution flowing into the second recovery space RS2 may be exhausted to the outside through a second recovery line 143. A third treatment solution flowing into the third recovery space RS3 may be exhausted to the outside through a third recovery line 145.

Meanwhile, the treatment container 100 may be combined with an elevating unit 600 that changes a vertical position of the treatment container 100. The elevating unit 600 may linearly move the treatment container 100 in up and down directions. Since the treatment container 100 moves in the up and down directions, a relative height of the treatment container 100 with respect to the spin head 210 may be changed.

The elevating unit 600 may include a bracket 612, a movement axis 614, and an actuator 616. The bracket 612 may be fixed and installed on an outer wall of the treatment container 100. The movement axis 614 movable by the actuator 616 in the up and down directions may be fixed on and coupled to the bracket 612. The treatment container 100 descends when the substrate W is loaded on the spin head 210 or is unloaded from the spin head 210, and thus, the spin head 210 protrudes from a top end of the treatment container 100. In addition, the vertical position of the treatment container 100 may be adjusted according to a kind of the treatment solution supplied onto the substrate W during the process in such a way that the treatment solution flows into the predetermined intake ducts 110, 120, and 130. Thus, relative vertical positions between the treatment container 100 and the substrate W may be changed. As a result, kinds of the treatment solutions and contamination gases respectively recovered through the recovery spaces RS1, RS2, and RS3 may be different from each other.

In the present embodiment, the substrate-treating apparatus 1 may vertically move the treatment container 100 to change the relative vertical positions between the treatment container 100 and the support unit 200. However, the inventive concepts are not limited thereto. In another embodiment, the substrate-treating apparatus 1 may vertically move the support unit 200 to change the relative vertical positions between the treatment container 100 and the support unit 200.

The support unit 200 may be installed within the treatment container 100. The support unit 200 may support the substrate W during the process and may be rotated during the process by a driving part 230 to be described later. The support unit 200 may include the spin head 210 having a circular top surface and may further include support pins 212 and chucking pins 214 which are disposed on the top surface of the spin head 210. The support pins 212 may support the substrate W. The support pins 212 may be spaced apart from an edge of the top surface of the spin head 210 and may be arranged by equal intervals. In addition, the support pins 212 may protrude upward from the spin head 210. The support pins 212 may support a bottom surface of the substrate W in such a way that the substrate W may be spaced apart from the spin head 210 in an up direction. The chucking pins 214 may be disposed at an outer side of the support pins 212 and may protrude upward. The chucking pins 214 may align the substrate W supported by the support pins 212 in such a way that the substrate W is disposed at a regular position on the spin head 210. The chucking pins 214 may be in contact with a sidewall of the substrate W during the process to prevent the substrate W from escaping from the regular position.

A support axis 220 supporting the spin head 210 may be connected to a bottom surface of the spin head 210. The support axis 220 may be rotated by a driving part 230 connected to a bottom end of the support axis 220. The driving part 230 may include, for example, a motor. Since the support axis 220 is rotated, the spin head 210 and the substrate W may also be rotated.

The nozzle part 300 may be disposed outside the treatment container 100. The nozzle part 300 may supply the solution, which is used to clean or etch the substrate W, to the substrate W fixed on the support unit 200. The nozzle part 300 may include a support axis 302, an actuator 303, a nozzle supporter 304, and the nozzle unit 310.

A longitudinal direction of the support axis 302 may be parallel to the third direction, and a bottom end of the support axis 302 may be coupled to the actuator 303. The actuator 303 may rotate and vertically move the support axis 302. One end of the support axis 302 may be connected to the actuator 303, and the nozzle supporter 304 may be connected to another end of the support axis 302 opposite to the one end of the support axis 302. The nozzle supporter 304 may be perpendicular to the support axis 302. The nozzle unit 310 may be installed on a bottom surface of an end portion of the nozzle supporter 304. The nozzle unit 310 may move between a process position and a standby position by the actuator 303. The process position corresponds to a position where the nozzle unit 310 is vertically disposed over a center of the substrate W, and the standby position corresponds to a position where the nozzle unit 310 is beyond the top surface of the substrate W. The nozzle unit 210 will be described in more detail later.

The exhaust member 400 may provide exhaust pressure (or suction pressure) to at least one, recovering the treatment solution, of the first to third intake ducts 110, 120, and 130. The exhaust member 400 may include the sub-exhaust line 410 connected to the exhaust duct 190 and a damper 420. The sub-exhaust line 410 may receive the exhaust pressure from an exhaust pump (not shown) and may be connected to a main exhaust line laying in a bottom space of a semiconductor product line (e.g., a FAB).

The fixed nozzles 500 may be installed on the top end of the treatment container 100. The fixed nozzle 500 may spray the treatment fluid onto the substrate W disposed on the spin head 210. A spraying angle of the fixed nozzle 500 may be adjusted according to a treating position of the substrate W.

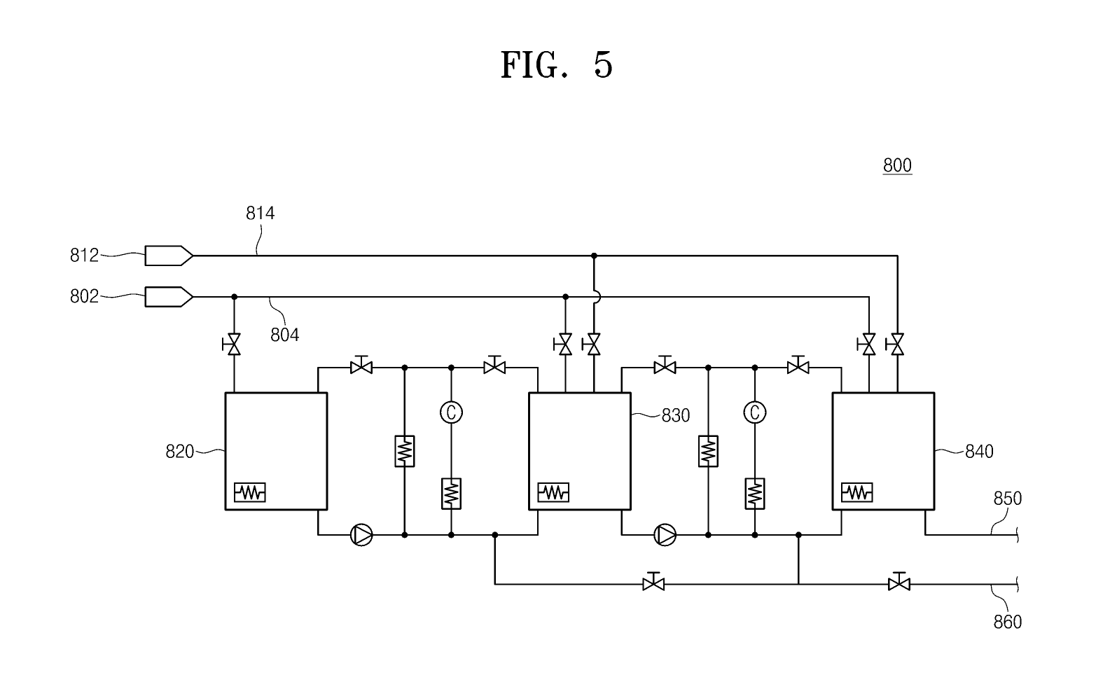

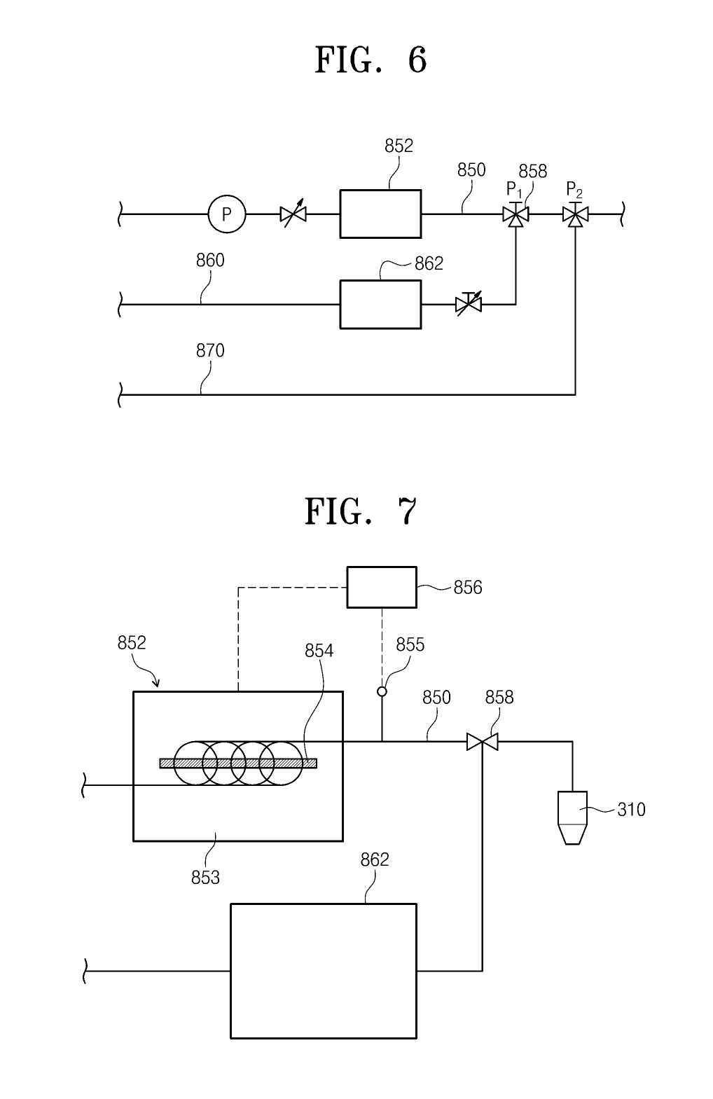

FIG. 5 is a schematic diagram illustrating the solution supply unit 800 according to an embodiment of the inventive concepts. FIG. 6 is a diagram illustrating a solution supply line 850 of FIG. 5. FIG. 7 is a diagram illustrating an embodiment of the inside of the solution supply line 850 of FIG. 6. Hereinafter, the solution supply unit 800 will be described with reference to FIGS. 5 to 7.

Referring to FIGS. 5 to 7, the solution supply unit 800 supplies a solution to the nozzle unit 310 of the substrate-treating apparatus 1. The solution supply unit 800 may include a solution supply source 802, a supply line 804, a dilution-solution supply source 812, a dilution-solution supply line 814, a heating tank 820, a correction tank 830, a supply tank 840, a solution supply line 850, a switching valve 858, a controller 856, and a recovery line 860.

The solution supply source 802 may supply the solution into each of the heating tank 820, the correction tank 830, and the supply tank 840. The supply line 804 may connect the solution supply source 802 to each of the heating tank 820, the correction tank 830, and the supply tank 840. For example, the solution may include phosphoric acid. The dilution-solution supply source 812 may supply a dilution solution to each of the correction tank 830 and the supply tank 840. The dilution-solution supply line 814 may connect the dilution-solution supply source 812 to each of the correction tank 830 and the supply tank 840. For example, the dilution solution may be pure water (e.g., deionized water).

The heating tank 820 may receive the solution from the solution supply source 802 and may store the received solution. The heating tank 820 may heat the solution therein to a set temperature. The heating tank 820 may rapidly heat the solution to the set temperature. In an embodiment, the set temperature may be higher than a boiling point of the solution. If the solution in the heating tank 820 reaches the set temperature, the heating tank 820 may supply the solution into the correction tank 830.

The correction tank 830 may receive the heated solution from the heating tank 820 and may store the received solution. The correction tank 830 may adjust a concentration and a temperature of the solution to desired values, respectively. The correction tank 830 may precisely control the concentration and the temperature of the received solution. In addition, the correction tank 830 may adjust the temperature and the concentration according to a set level of the solution therein. Since the solution is heated at the temperature equal to or greater than its boiling point in the heating tank 820, the solution may be evaporated. Thus, the concentration of the solution may be varied compared with the desired value. In this case, the correction tank 830 may correct the concentration of the solution to the desired value. In addition, the correction tank 830 may adjust the solution therein to the set level.

The supply tank 840 may receive the solution from the correction tank 830 and may store the received solution. The supply tank 840 may supply the stored solution into the process chamber 700. The supply tank 840 may continuously supply the solution having the controlled temperature and concentration into the process chamber 700. In some embodiments, the supply tank 840 may include a temperature and concentration correction device.

The solution supply unit 800 may further include a circulation line. The heating tank 820 and the correction tank 830 may be connected to each other by the circulation line, and the correction tank 830 and the supply tank 840 may also be connected to each other by the circulation line.

The solution supply line 850 may connect the supply tank 840 to the nozzle unit 310. The solution supply line 850 may supply the solution into the nozzle unit 310. A heating member 852 may be installed on the solution supply line 850. The heating member 852 may reheat the solution first heated in the tanks 820, 830, and 840 of the solution supply unit 800 before the solution is supplied into the nozzle unit 310. In an embodiment, the heating member 852 may be an in-line heater 852 that is installed in-line on the solution supply line 850. As illustrated in FIG. 7, the in-line heater 852 may include a cartridge heater 854 and a lagging 853 therein. In addition, the solution supply line 850 surrounding the cartridge heater 854 may be formed of a double pipe. For example, a Teflon-based plastic (PFA) may be lined on the inside of a pipe of a stainless material (SUS) to form the double pipe, so the double pipe may indirectly transmit heat.

The recovery line 860 may diverge from the solution supply line 850. The recovery line 860 may diverge from the solution supply line 850 at a first point P1.

The first point P1 may be disposed downstream from the heating member 852. Here, the first point P1 may be adjacent to the heating member 852. A cooling unit 862 may be installed on the recovery line 860. The cooling unit 862 may cool the solution 860 flowing through the recovery line 860. The cooling unit 862 may be provided to be adjacent to the switching valve 858. The recovery line 860 may be connected to the circulation line. In some embodiments, the recovery line 860 may be connected to the supply tank 840. If the process is not performed, the recovery line 860 may recover the solution. The cooling unit 862 may be provided on the recovery line 860 and may be adjacent to the switching valve 858, so the solution heated by the heating member 852 may be cooled by the cooling unit 862. Thus, a temperature difference between the recovery line 860 and another pipe may be reduced to reduce the influence of the solution on the pipe.

The switching valve 858 may be installed at the first point P1. The switching valve 858 may switch a supply direction of the solution between the nozzle unit 310 and the recovery line 860.

The controller 856 may control the solution supply unit 800. The controller 856 may switch the switching valve between the nozzle unit 310 and the recovery line 860. In an embodiment, if the process is performed in the process chamber 700, the controller 856 may control the switching valve 858 to supply the solution in the solution supply line 850 to the nozzle unit 310. On the contrary, if the process is not performed, the controller 856 may control the switching valve 858 to supply the solution passing through the heating member 852 to the recovery line 860. In addition, the controller 856 may control the solution supply unit 800 according to a supply time and a kind of the solution. Furthermore, the controller 856 may control the temperature of the solution heated in the heating member 852 by means of a thermometer 855 installed downstream from the heating member 852. The controller 856 may control a heating time and a heating temperature of the heating member 852 according to the temperature of the solution passing through the heating member 852. Thus, the temperature of the solution, which corresponds to an important factor, may be precisely controlled. Here, the controller 856 may be a process module controller.

An additive supply line 870 may be connected to the solution supply line 850. The additive supply line 870 may supply an additive. Here, the additive may include a chemical material of which a boiling point is different from that of the solution. Referring again to FIG. 6, the additive supply line 870 may be connected to a second point P2 of the solution supply line 850. The second point P2 may be disposed downstream from the first point P1. Since the additive supply line 870 is connected to the solution supply line 850, a mixture fluid of the additive and the solution may be supplied into the nozzle unit 310.

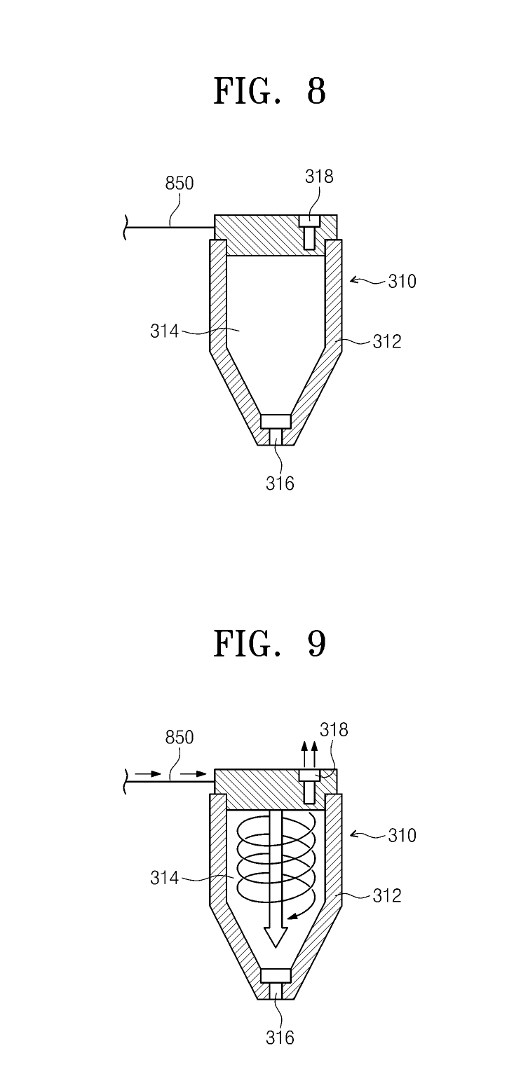

FIG. 8 illustrates the inside of the nozzle unit 310 of FIG. 5. FIG. 9 illustrates a fluid flowing through the nozzle unit 310 of FIG. 8. The nozzle unit 310 may include a body 312, an outlet 316, and an exhaust pipe 318. The body 312 may define an inner space 314 in which the solution is stored. A width of the body 312 may be progressively less toward a bottom end of the body 312. The outlet 316 may discharge the solution onto the substrate. The exhaust pipe 318 may exhaust an air bubble to the outside of the body 312. The exhaust pipe 318 may be provided in an upper portion of the nozzle unit 310. If the solution is mixed with the additive, an eddy may be formed in the inner space 314 by a pressure difference, so the solution and the additive may be mixed with each other. In addition, since the solution heated at a high temperature is provided, the solution or the additive may form the air bubble in the inner space 314. The air bubble may be exhausted to the exhaust pipe 318 through an upper air layer formed by the eddy, and thus, it is possible to prevent a particle from occurring on the substrate by the air bubble.

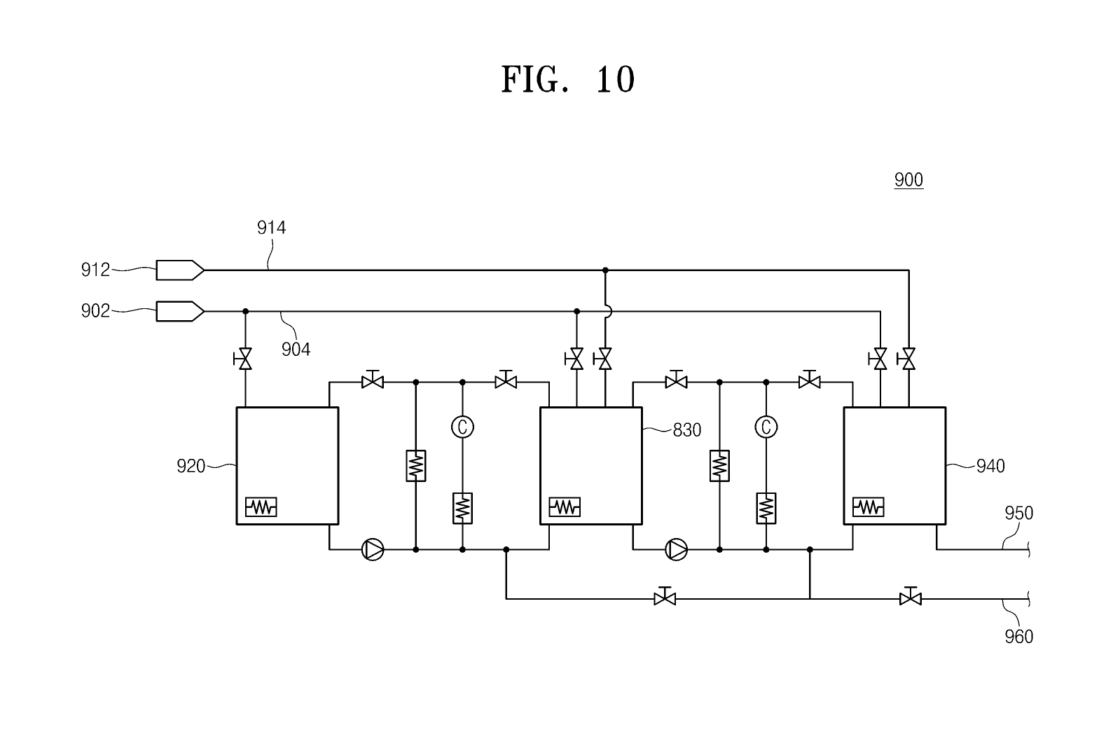

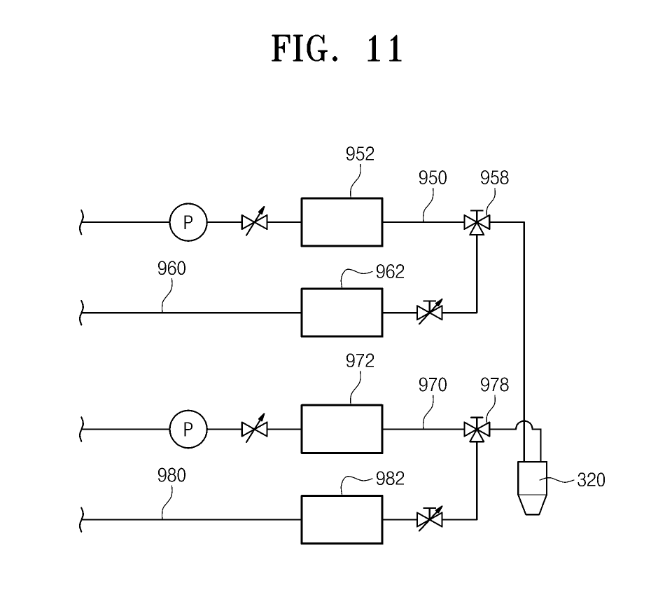

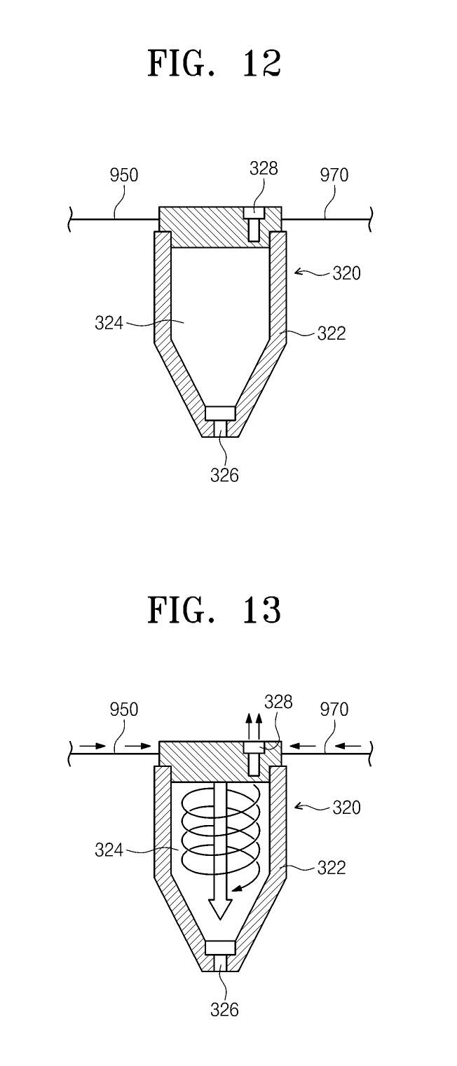

FIG. 10 is a diagram illustrating a solution supply unit 900 according to another embodiment of the inventive concepts. FIG. 11 is a diagram illustrating a solution supply line 950 of FIG. 10. FIG. 12 illustrates the inside of a nozzle unit 320 of FIG. 11. FIG. 13 illustrates a fluid flowing through the nozzle unit 320 of FIG. 12. A solution supply unit may include a solution supply source 902, a supply line 904, a dilution-solution supply source 912, a dilution-solution supply line 914, a heating tank 920, a correction tank 930, a supply tank 940, a solution supply line 950, a switching valve 958, a controller 956, a recovery line 960, and an additive supply line 970. The solution supply source 902, the supply line 904, the dilution-solution supply source 912, the dilution-solution supply line 914, the heating tank 920, the correction tank 930, the supply tank 940, the solution supply line 950, the switching valve 958, the controller 956, and the recovery line 960 of FIG. 10 may have the same shapes and functions as or similar shapes and functions to the solution supply source 802, the supply line 804, the dilution-solution supply source 812, the dilution-solution supply line 814, the heating tank 820, the correction tank 830, the supply tank 840, the solution supply line 850, the switching valve 858, the controller 856, and the recovery line 860 of FIGS. 5, 6, and 7, respectively. However, the additive supply line 970 may be connected directly to a body 322 of the nozzle unit 320, not to the solution supply line 950. In addition, the additive supply line 970 may include a heating member 972, a recovery line 980, and a switching valve 978. At this time, an additive may include a chemical material of which a boiling point is different from that of the solution. The solution and the additive may be supplied into the body 322 through lines different from each other, and thus, an eddy may be actively formed in the inner space of the nozzle unit 320. As a result, the nozzle unit 320 may exhaust an air bubble through an exhaust pipe 328, so a particle caused by the air bubble may be prevented. In an embodiment, the additive supply line 970 may be a single supply line.

The solution supply unit 800 supplying the dilution solution to the correction tank 830 and the supply tank 840 is described as an example in the aforementioned embodiment. However, the inventive concepts are not limited thereto.

In other embodiments, the dilution solution may also be supplied to the heating tank 820. In addition, a supply pipe may be provided in the heating tank 820. Furthermore, the solution supply unit 800 may include a liquid flow controller (LFC).

The treatment solution supply unit described above may be used in various processes as well as the process of etching the substrate. For example, the treatment solution supply unit may be used in a process of cleaning the substrate.

Some embodiments of the inventive concepts may provide the substrate-treating apparatus capable of improving the etch rate.

In addition, some embodiments of the inventive concepts may provide the substrate-treatment apparatus capable of supplying the solution with the effectively control temperature.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. An apparatus for treating a substrate, the apparatus comprising:
a treatment container having a treatment space therein;
a support unit supporting the substrate in the treatment space;
a nozzle unit discharging a solution onto the substrate supported by the support unit; and
a solution supply unit supplying the solution to the nozzle unit,
wherein the solution supply unit comprises:
a solution supply line connected to the nozzle unit;
a heating member installed on the solution supply line to heat the solution; and
a recovery line diverging from the solution supply line at a first point disposed downstream from the heating member.

2. The apparatus of claim 1, wherein a cooling unit is installed on the recovery line to cool the solution.

3. The apparatus of claim 2, further comprising:
a controller controlling the solution supply unit; and
a switching valve installed at the first point to switch a supply direction of the solution between the nozzle unit and the recovery line,
wherein the controller controls the switching valve to supply the solution to the nozzle unit when a process is performed, and
wherein the controller controls the switching valve to supply the solution to the recovery line when the process is not performed.

4. The apparatus of claim 3, wherein the first point is adjacent to the heating member.

5. The apparatus of claim 4, wherein the cooling unit is adjacent to the switching valve.

6. The apparatus of claim 5, wherein the nozzle unit comprises:
a body defining an inner space in which the solution is stored;
an outlet discharging the solution onto the substrate; and
an exhaust pipe exhausting an air bubble formed in the inner space by the solution to the outside of the body.

7. The apparatus of claim 6, further comprising:
an additive supply line connected to the body and supplying an additive.

8. The apparatus of claim 6, further comprising:
an additive supply line connected to the solution supply line and supplying an additive.

9. The apparatus of claim 8, wherein the additive supply line is connected to the solution supply line at a second point disposed downstream from the first point.

10. The apparatus of claim 7, wherein the additive includes a chemical material of which a boiling point is different from that of the solution.

11. The apparatus of claim 10, wherein the heating member is an in-line heater installed in-line on the solution supply line.

12. The apparatus of claim 11, wherein the solution includes phosphoric acid, and
wherein the process is a process of etching a nitride layer formed on the substrate.

13. A method of treating a substrate using the apparatus of claim 1, the method comprising:
supplying the solution for treating a process from the solution supply unit to the nozzle unit,
wherein the solution is heated by the heating member on the solution supply line and is then supplied.

14. The method of claim 13, wherein the solution is supplied to the nozzle unit when the process is performed, and
wherein the solution is supplied to the recovery line when the process is not performed.

15. The method of claim 14, wherein a cooling unit cooling the solution is installed on the recovery line.

16. The method of claim 15, wherein the solution includes phosphoric acid, and
wherein the process is a process of etching a nitride layer formed on the substrate.

17. A method of treating a substrate by supplying a solution for treating a process onto a substrate through a nozzle unit, the method comprising:
supplying the solution to the nozzle unit by a solution supply unit,
wherein the solution is heated by a heating member installed on a solution supply line and is then supplied to the nozzle unit.

18. The method of claim 17, wherein the solution is supplied to the nozzle unit when the process is performed, and
wherein the solution is supplied to a recovery line connected to the solution supply line when the process is not performed.

19. The method of claim 18, wherein a cooling unit cooling the solution is installed on the recovery line.

20. The method of claim 19, wherein the solution includes phosphoric acid, and
wherein the process is a process of etching a nitride layer formed on the substrate.
